(19) United States
(12) Patent Application Publication
(10) Pub. No.: US 2026/0305180 A1
(43) Pub. Date: Oct. 1, 2026

(54) MAGNETIC DOMAIN WALL MOTION ELEMENT AND MAGNETIC ARRAY

(71) Applicant: TDK Corporation, Tokyo (JP)

(72) Inventor: Toshiki GUSHI, Tokyo (JP)

(73) Assignee: TDK Corporation, Tokyo (JP)

(21) Appl. No.: 19/091,952

(22) Filed: Mar. 27, 2025

(51) Int. Cl. H10N 50/80; H10N 50/10

(52) U.S. Cl. CPC H10N 50/80; H10N 50/10

(57) ABSTRACT

This magnetic domain wall motion element includes a magnetic domain wall motion layer, a first magnetization fixing portion, a second magnetization fixing portion, a first wiring, and a second wiring. The magnetic domain wall motion layer has a first magnetization fixed area, a second magnetization fixed area, and a magnetic domain wall motion area. The magnetic domain wall motion area is sandwiched between the first magnetization fixed area and the second magnetization fixed area in a first direction. The first wiring is connected to the first magnetization fixing portion, and the second wiring is connected to the second magnetization fixing portion. Each of the first wiring and the second wiring has a first part extending in the same direction as a second direction intersecting the first direction and a lamination direction with respect to the magnetic domain wall motion layer. Magnetization of the first magnetization fixed area is oriented in a direction which is an outer product of a direction in which the magnetic domain wall motion layer extends with respect to a first connection surface between the first magnetization fixing portion and the first wiring, and a direction in which the first part extends in the second direction with respect to the first connection surface.

### TECHNICAL FIELD

The present disclosure relates to a magnetic domain wall motion element and a magnetic array.

### BACKGROUND ART

Magnetoresistance effect elements utilizing a change in resistance value (magnetoresistance change) based on a change in relative angle of magnetization between two ferromagnetic layers are known. For example, the magnetic domain wall motion-type magnetoresistance effect element described in Patent Document 1 (which will hereinafter be referred to as a magnetic domain wall motion element) is an example of the magnetoresistance effect element. In magnetic domain wall motion elements, a resistance value in a lamination direction changes depending on a position of a magnetic domain wall, and data can be recorded in a multi-value form or an analog form. Magnetic domain wall motion elements have high linearity and symmetry in resistance change, have excellent rewriting durability, and are capable of high-speed operation.

### CITATION LIST

### Patent Document

Patent Document 1: PCT International Publication No. WO2022/185410

### SUMMARY OF INVENTION

### Technical Problem

A resistance value of a magnetic domain wall motion element in a lamination direction changes at a position of a magnetic domain wall, and the magnetic domain wall motion element stores data at the position of the magnetic domain wall. When the magnetic domain wall reaches one end side of a magnetic domain wall motion layer having a magnetic domain wall and the magnetic domain wall motion layer becomes a single magnetic domain, the magnetic domain wall disappears, and data cannot be read or written any longer. Therefore, in a magnetic domain wall motion element, a magnetization fixing portion may be formed such that a magnetic domain wall remains within a predetermined range. A structural defect is likely to occur at a boundary in a magnetic domain wall motion layer between a part in contact with the magnetization fixing portion and a part not in contact therewith, and the magnetic domain wall may be trapped in this structural defect. If the magnetic domain wall is trapped, the magnetic domain wall will not be able to operate appropriately, and the magnetic domain wall motion element may not function appropriately any longer.

The present disclosure has been made in consideration of the foregoing problems, and an object thereof is to provide a magnetic domain wall motion element and a magnetic memory, in which trapping of a magnetic domain wall in the vicinity of a magnetization fixing portion can be curbed.

### Solution to Problem

A magnetic domain wall motion element according to a first aspect includes a magnetic domain wall motion layer, a first magnetization fixing portion, a second magnetization fixing portion, a first wiring, and a second wiring. The magnetic domain wall motion layer has a first magnetization fixed area, a second magnetization fixed area, and a magnetic domain wall motion area. The magnetic domain wall motion area is sandwiched between the first magnetization fixed area and the second magnetization fixed area in a first direction. The first magnetization fixing portion is connected to the first magnetization fixed area. The second magnetization fixing portion is connected to the second magnetization fixed area. The first wiring is connected to the first magnetization fixing portion. The second wiring is connected to the second magnetization fixing portion. Each of the first wiring and the second wiring has a first part extending in the same direction as a second direction intersecting the first direction and a lamination direction with respect to the magnetic domain wall motion layer. The magnetization of the first magnetization fixed area is oriented in a direction which is an outer product of a direction in which the magnetic domain wall motion layer extends based on a first connection surface between the first magnetization fixing portion and the first wiring, and a direction in which the first part extends in the second direction with respect to the first connection surface.

### Advantageous Effects of Invention

In the magnetic domain wall motion element and the magnetic array according to the foregoing aspects, trapping of a magnetic domain wall in the vicinity of a magnetization fixing portion can be curbed.

### BRIEF DESCRIPTION OF DRAWINGS

FIG. 1 A block diagram of a magnetic array according to a first embodiment.

FIG. 2 A circuit diagram of an integrated area of the magnetic array according to the first embodiment.

FIG. 3 A plan view of a part in the vicinity of a magnetic domain wall motion element of the magnetic array according to the first embodiment.

FIG. 4 A cross-sectional view of the magnetic domain wall motion element according to the first embodiment.

FIG. 5 Another cross-sectional view of the magnetic domain wall motion element according to the first embodiment.

FIG. 6 An enlarged view of a part in the vicinity of a first magnetization fixing portion of the magnetic domain wall motion element according to the first embodiment.

FIG. 7 An explanatory view of writing operation of the magnetic domain wall motion element according to the first embodiment.

FIG. 8 A cross-sectional view of the magnetic domain wall motion element according to a first modification example.

FIG. 9 A plan view of a part in the vicinity of the magnetic domain wall motion element of the magnetic array according to a second modification example.

FIG. 10 A plan view of a part in the vicinity of a magnetic domain wall motion element of the magnetic array according to a second embodiment.

FIG. 11 An explanatory view of writing operation of the magnetic domain wall motion element according to the second embodiment.

FIG. 12 A plan view of a part in the vicinity of a magnetic domain wall motion element of the magnetic array according to a third embodiment.

FIG. 13 A plan view of a part in the vicinity of a magnetic domain wall motion element of the magnetic array according to a fourth embodiment.

FIG. 14 A schematic view of a neural network.

### DESCRIPTION OF EMBODIMENTS

Hereinafter, the present embodiment will be described in detail suitably with reference to the drawings. In the drawings used in the following description, in order to make characteristics of the present disclosure easy to understand, characteristic parts may be shown in an enlarged manner for the sake of convenience, and dimensional ratios or the like of each constituent element may differ from actual values thereof. Materials, dimensions, and the like shown in the following description are merely exemplary examples. The present disclosure is not limited thereto and can be suitably changed and performed within a range in which the effects of the present disclosure are exhibited.

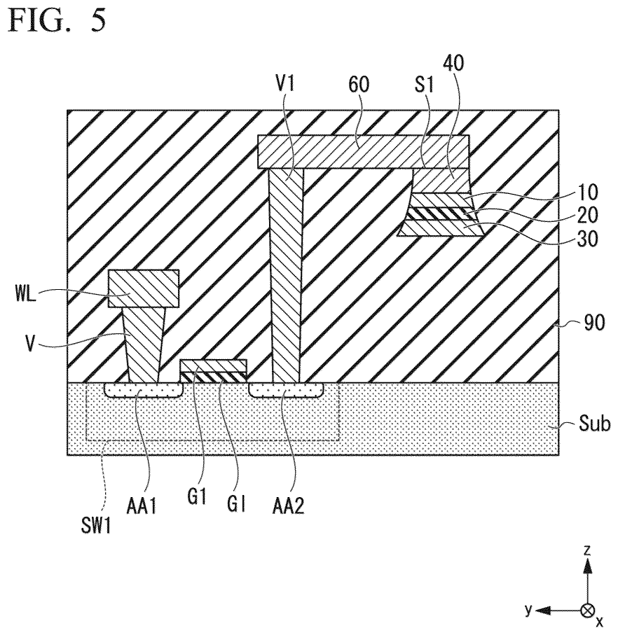

First, directions will be defined. An x direction and a y direction are directions substantially parallel to a surface of a substrate Sub (refer to FIG. 5), which will be described below. The x direction is a direction in which a magnetic domain wall motion layer (which will be described below) extends. A direction from a first magnetization fixing portion toward a second magnetization fixing portion will be referred to as a positive x direction, and a direction opposite thereto will be referred to as a negative x direction. When these are not distinguished from each other, they will be simply referred to as the x direction. The y direction is a direction orthogonal to the x direction within an xy plane. A z direction is a lamination direction of each of the layers. The z direction is orthogonal to the x direction and the y direction. A direction from the substrate Sub toward a magnetic domain wall motion element will be referred to as a positive z direction, and a direction opposite thereto will be referred to as a negative z direction. The x direction, the y direction, and the z direction indicate a right-handed coordinate system. In this specification, the positive z direction may be expressed as “upward”, and the negative z direction may be expressed as “downward”, but these expressions are used for the sake of convenience and do not define the direction of gravity.

In addition, in this specification, for example, the expression “extending in the x direction” means that the dimension in the x direction is larger than the smallest dimension among respective dimensions in the x direction, the y direction, and the z direction. The same applies to the cases of extending in other directions. In addition, in this specification, the term “connect” is not limited to the case of being directly connected and also includes a case of being connected with another object therebetween.

### First Embodiment

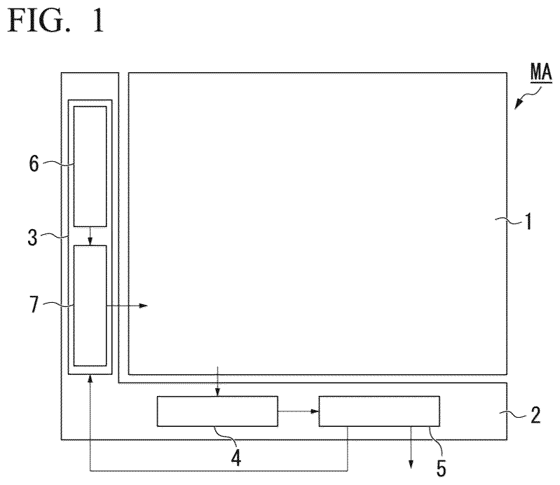

FIG. 1 is a block diagram of a magnetic array MA according to a first embodiment. The magnetic array MA has an integrated area 1 and a peripheral area 2.
For example, the magnetic array MA can be utilized in magnetic memories, product-sum operation units, neuromorphic devices, spin memristors, and magneto-optic elements.

The integrated area 1 is an area in which a plurality of magnetic domain wall motion elements are integrated.

When the magnetic array MA is used as a memory, data is accumulated in the integrated area 1. Each of the plurality of magnetic domain wall motion elements serves as a memory for storing data. When the magnetic array MA is used as a neuromorphic device, learning and inference are performed in the integrated area 1. Each of the plurality of magnetic domain wall motion elements functions as a memristor performing multiplication operation. A memristor is a passive element in which electric charge that has passed therethrough is stored and its conductance and resistance change in accordance therewith. A memristor outputs a current corresponding to the product of an input voltage and a conductance value of itself.

The peripheral area 2 is an area in which a control element for controlling operation of the magnetic domain wall motion elements within the integrated area 1 is mounted. For example, the peripheral area 2 has a pulse application device 3, a resistance detection device 4, and an output unit 5.

The pulse application device 3 is constituted to be able to apply a pulse to at least one of the plurality of magnetic domain wall motion elements within the integrated area 1. For example, the pulse application device 3 has a control unit 6 and a power source 7.

For example, the control unit 6 has a processor and a memory. For example, the processor is a central processing unit (CPU). The processor operates on the basis of a control program stored in the memory. Details of the control program will be described below. For example, the control unit 6 controls an address of a magnetic domain wall motion element to which a pulse is to be applied, a writing pulse (voltage, pulse length) applied to a predetermined magnetic domain wall motion element, and the like. Furthermore, the control unit 6 may have, a clock, a counter, a random number generator, and the like. The clock serves as an indicator for timing of applying a pulse, and the counter counts the number of times or the like a pulse has been applied. The power source 7 applies a pulse toward the magnetic domain wall motion elements in response to an instruction from the control unit 6.

The resistance detection device 4 is constituted to be able to detect resistance values of the magnetic domain wall motion elements within the integrated area 1. The resistance detection device 4 may detect resistances of the respective magnetic domain wall motion elements within the integrated area 1. For example, it may detect the total resistance of the magnetic domain wall motion elements which belong to the same column. For example, the resistance detection device 4 has a comparator which compares magnitudes of detected resistance values. For example, the comparator may compare detected resistance values with each other or may compare a reference resistance value set in advance with detected resistance values.

The output unit 5 is connected to the resistance detection device 4. For example, the output unit 5 has a processor, an output capacitor, an amplifier, a converter, and the like. When the magnetic array MA is used as a neuromorphic device, the output unit 5 may perform arithmetic operation of substituting detection results of the resistance detection device 4 into an activation function. For example, the arithmetic operation is performed by the processor. The output unit 5 outputs the arithmetic operation results to the outside. When the magnetic array MA is used as a neuromorphic device, for example, an operation, such as outputting arithmetic operation results as an input signal of another magnetic array, may be performed, or an operation, such as outputting it to the outside as an identification rate, may be performed. In addition, the output unit 5 may feed back the arithmetic operation results to the pulse application device 3.

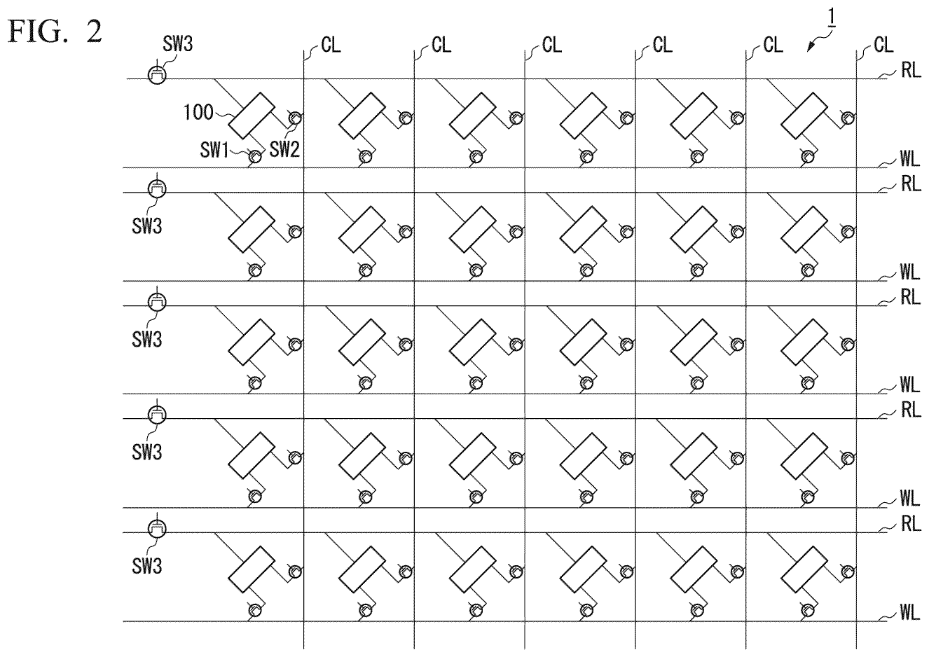

FIG. 2 is a circuit diagram of the integrated area 1 according to the first embodiment. The integrated area 1 includes a plurality of magnetic domain wall motion elements 100, a plurality of writing wirings WL, a plurality of common wirings CL, a plurality of reading wirings RL, a plurality of first switching elements SW1, and a plurality of second switching elements SW2. For example, third switching elements SW3 may belong to the pulse application device 3 of the peripheral area 2.

For example, the plurality of magnetic domain wall motion elements 100 are arrayed in a matrix shape. The plurality of magnetic domain wall motion elements 100 are not limited to those in which real elements are arrayed in a matrix shape and may be arrayed in a matrix in a circuit diagram.

Each of the writing wirings WL is a wiring used when data is written in the magnetic domain wall motion element 100. Each of the writing wirings WL electrically connects the pulse application device 3 and one or more magnetic domain wall motion elements 100 to each other. Each of the common wirings CL is a wiring which can be used both when writing and reading data. For example, each of the common wirings CL is connected to the resistance detection device 4. The common wiring CL may be provided in each of the plurality of magnetic domain wall motion elements 100 or may be provided across the plurality of magnetic domain wall motion elements 100. Each of the reading wirings RL is a wiring used when data is read from the magnetic domain wall motion element 100. Each of the reading wirings RL electrically connects the pulse application device 3 and one or more magnetic domain wall motion elements 100 to each other.

The first switching elements SW1, the second switching elements SW2, and the third switching elements SW3 are elements for controlling a flow of a current. For example, the first switching elements SW1, the second switching elements SW2, and the third switching elements SW3 are transistors. For example, the first switching elements SW1, the second switching elements SW2, and the third switching elements SW3 may be elements such as ovonic threshold switches (OTS) utilizing phase change in a crystal layer, elements such as metal insulator transfer (MIT) switches utilizing variation in a band structure, elements such as Zener diodes and avalanche diodes utilizing a breakdown voltage, or elements whose conductivity varies in accordance with variation in atom positions.

For example, the first switching element SW1 and the second switching element SW2 are each connected to one magnetic domain wall motion element 100. For example, the first switching element SW1 is connected between the magnetic domain wall motion element 100 and the writing wiring WL. For example, the second switching element SW2 is connected between the magnetic domain wall motion element 100 and the common wiring CL. For example, the third switching element SW3 is connected across the plurality of magnetic domain wall motion elements 100. For example, the third switching element SW3 is connected to the reading wiring RL.

The positional relationships between the first switching elements SW1, the second switching elements SW2, and the third switching elements SW3 are not limited to the case shown in FIG. 2. For example, the first switching element SW1 may be connected across the plurality of magnetic domain wall motion elements 100 and positioned upstream of the writing wiring WL. In addition, for example, the second switching element SW2 may be connected across the plurality of magnetic domain wall motion elements 100 and positioned upstream of the common wiring CL. In addition, for example, the third switching elements SW3 each may be connected to one magnetic domain wall motion element 100.

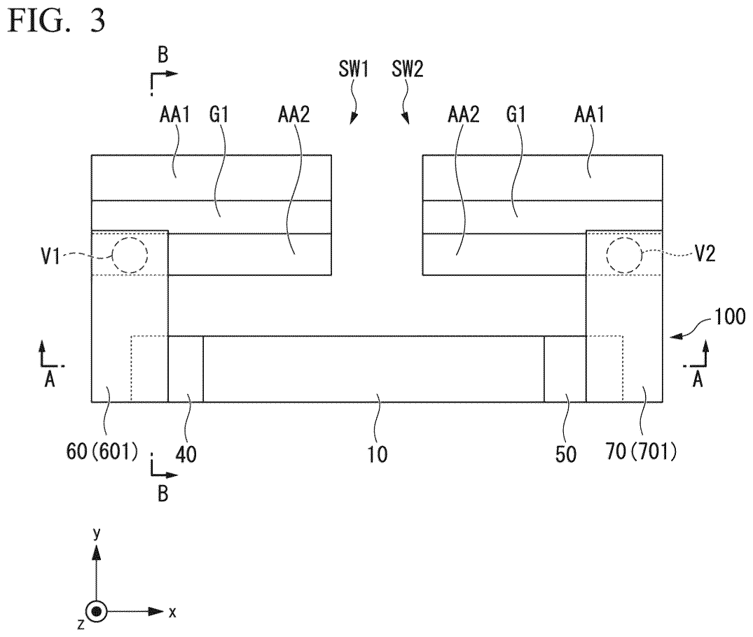

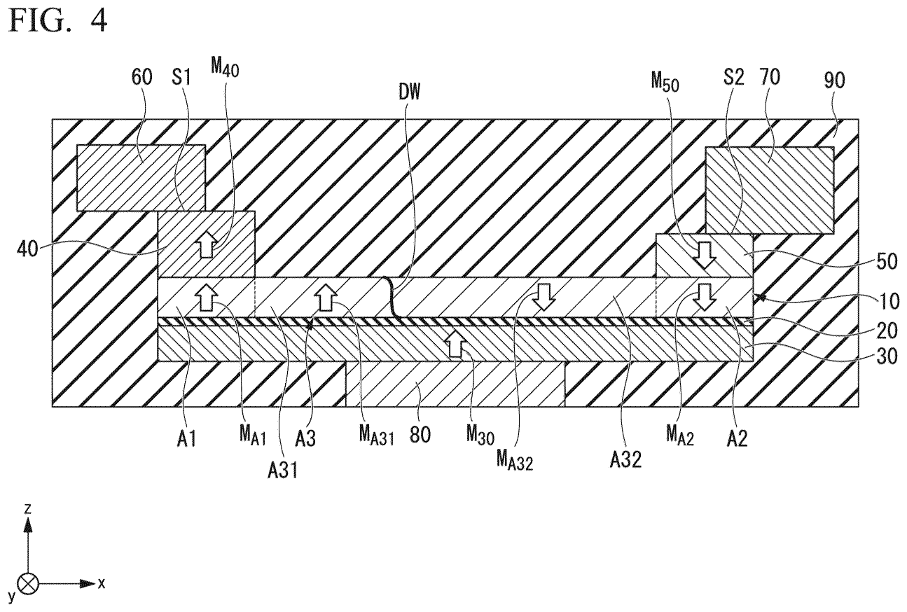

FIG. 3 is a plan view of a part in the vicinity of the magnetic domain wall motion element 100 of the magnetic array MA according to the first embodiment. FIG. 4 is a cross-sectional view cut along line A-A in FIG. 3, and FIG. 5 is a cross-sectional view cut along line B-B in FIG. 3.

The first switching element SW1 and the second switching element SW2 shown in FIGS. 3 and 5 are transistors. The transistors each have a gate electrode G, a gate insulation film GI, and a first active area AA1 and a second active area AA2 formed in the substrate Sub. The first active area AA1 and the second active area AA2 each serve as a source or a drain of the transistor depending on a flowing direction of a current. For example, the substrate Sub is a semiconductor substrate. The third switching element SW3 is electrically connected to a third wiring 80 and is located at a position shifted in the x direction in FIG. 5, for example.

The transistors and the magnetic domain wall motion element 100 are located in different layers, and these are connected to each other via the via wirings extending in the z direction. The first switching element SW1 and the magnetic domain wall motion element 100 are connected to each other via a first via wiring V1, and the second switching element SW2 and the magnetic domain wall motion element 100 are connected to each other via a second via wiring V2. In addition, the writing wiring WL, the common wiring CL, and the reading wiring RL are also connected to each switching element via the via wirings V.

The first switching element SW1 and the second switching element SW2 are separated from the magnetic domain wall motion element 100 by an insulation layer 90. The insulation layer 90 is an insulation layer providing insulation between wirings of multilayer wirings or between elements. For example, the insulation layer 90 is made of silicon oxide (SiOₓ), silicon nitride (SiNₓ), silicon carbide (SiC), chromium nitride (CrN), silicon carbonitride (SiCN), silicon oxynitride (SiON), aluminum oxide (Al₂O₃), zirconium oxide (ZrOₓ), or the like.

For example, the magnetic domain wall motion element 100 has a magnetic domain wall motion layer 10, a nonmagnetic layer 20, a reference layer 30, a first magnetization fixing portion 40, a second magnetization fixing portion 50, a first wiring 60, a second wiring 70, and the third wiring 80.

The magnetic domain wall motion layer 10 extends in the x direction. The magnetic domain wall motion layer 10 internally has a plurality of magnetic domains and has magnetic domain walls DW at boundaries between the plurality of magnetic domains. For example, the magnetic domain wall motion layer 10 is a layer capable of magnetically recording information by changing a magnetic state. The magnetic domain wall motion layer 10 is also referred to as an analog layer or a magnetic recording layer.

The magnetic domain wall motion layer 10 has a first area A1, a second area A2, and a third area A3. The first area A1 is an area overlapping the first magnetization fixing portion 40 when viewed in the z direction. The second area A2 is an area the second magnetization fixing portion 50 overlapping when viewed in the z direction. The third area A3 is an area other than the first area A1 and the second area A2 of the magnetic domain wall motion layer 10. For example, the third area A3 is an area sandwiched between the first area A1 and the second area A2 in the x direction.

Magnetization M_{A1} of the first area A1 is fixed due to magnetization M₄₀ of the first magnetization fixing portion 40. The first area A1 is an example of a first magnetization fixed area. The magnetization M_{A1} of the first area A1 is oriented in a direction which is an outer product of a direction in which the magnetic domain wall motion layer 10 extends with respect to a first connection surface S1, and a direction in which a first part 601 extends with respect to the first connection surface S1. The first part 601 is a part extending in the y direction in the first wiring 60. The first connection surface S1 is a surface where the first magnetization fixing portion 40 and the first wiring 60 are connected. The magnetic domain wall motion layer 10 extends in the positive x direction and the first part 601 extends in the positive y direction with respect to the first connection surface S1. The direction of the outer product of the positive x direction and the positive y direction is the positive z direction. The magnetization M_{A1} of the first area A1 is oriented in the positive z direction.

Magnetization M_{A2} of the second area A2 is fixed due to magnetization M₅₀ of the second magnetization fixing portion 50. The second area A2 is an example of a second magnetization fixed area. The magnetization M_{A2} of the second area A2 is oriented in a direction which is an outer product of a direction in which the magnetic domain wall motion layer 10 extends with respect to a second connection surface S2, and a direction in which a first part 701 extends with respect to the second connection surface S2. The first part 701 is a part extending in the y direction in the second wiring 70. The second connection surface S2 is a surface where the second magnetization fixing portion 50 and the second wiring 70 are connected. The magnetic domain wall motion layer 10 extends in the negative x direction and the first part 601 extends in the positive y direction with respect to the second connection surface S2. The direction of the outer product of the negative x direction and the positive y direction is the negative z direction. The magnetization M_{A2} of the second area A2 is oriented in the negative z direction.

Here, magnetization being fixed denotes that magnetization is not reversed during normal operation (no external force exceeding an expected level is applied) of the magnetic domain wall motion element 100. For example, magnetization orientation directions of the first area A1 and the second area A2 are opposite to each other.

The third area A3 is an area in which the magnetization direction changes and the magnetic domain wall DW can move. The third area A3 is an example of a magnetic domain wall motion area. The third area A3 has a first magnetic domain A31 and a second magnetic domain A32. The magnetization orientation directions of the first magnetic domain A31 and the second magnetic domain A32 are opposite to each other. The boundary between the first magnetic domain A31 and the second magnetic domain A32 is the magnetic domain wall DW. For example, magnetization M_{A31} of the first magnetic domain A31 is oriented in the same direction as that of the magnetization M_{A1} of the first area A1. For example, magnetization M_{A32} of the second magnetic domain A32 is oriented in the same direction as that of the magnetization M_{A2} of the adjacent second area A2.

If the volume ratio between the first magnetic domain A31 and the second magnetic domain A32 within the third area A3 changes, the magnetic domain wall DW moves. The magnetic domain wall DW moves by causing a writing current to flow in the x direction of the third area A3, applying an external magnetic field to the third area A3, or the like. For example, if a writing current (for example, a current pulse) in the positive x direction is applied to the third area A3, electrons flow in the negative x direction opposite to the current, and therefore the magnetic domain wall DW moves in the negative x direction. When a current flows from the first magnetic domain A31 toward the second magnetic domain A32, spin-polarized electrons in the second magnetic domain A32 cause magnetization reversal of the magnetization M_{A31} of the first magnetic domain A31. Due to the reversed magnetization M_{A31} of the first magnetic domain A31, the magnetic domain wall DW moves in the negative x direction.

The magnetic domain wall motion layer 10 is constituted using a magnetic material. The magnetic domain wall motion layer 10 may be made of a ferromagnetic material, a ferrimagnetic material, or a combination of one of these and an antiferromagnetic material whose magnetic state can be changed by a current. The magnetic domain wall motion layer 10 preferably has at least one element selected from the group consisting of Co, Ni, Fe, Pt, Pd, Gd, Tb, Mn, Ge, and Ga. Examples of materials used for the magnetic domain wall motion layer 10 include a laminated film of Co and Ni, a laminated film of Co and Pt, a laminated film of Co and Pd, a MnGa-based material, a GdCo-based material, and a TbCo-based material. A ferrimagnetic material such as a MnGa-based material, a GdCo-based material, or a TbCo-based material has small saturation magnetization so that a small amount of threshold current is required to move the magnetic domain wall DW. In addition, a laminated film of Co and Ni, a laminated film of Co and Pt, and a laminated film of Co and Pd have a significant coercive force so that the magnetic domain wall DW has a low movement speed. Examples of antiferromagnetic materials include Mn₃X (X is Sn, Ge, Ga, Pt, Ir, or the like), CuMnAs, and Mn₂Au. A material similar to that of the reference layer 30 (which will be described below) can also be applied to the magnetic domain wall motion layer 10.

The nonmagnetic layer 20 is positioned between the magnetic domain wall motion layer 10 and the reference layer 30. The nonmagnetic layer 20 is laminated on one surface of the reference layer 30.

For example, the nonmagnetic layer 20 is made of a nonmagnetic insulating material, a nonmagnetic semiconductor, or a nonmagnetic metal. For example, a nonmagnetic insulating material is Al₂O₃, SiO₂, MgO, MgAl₂O₄, or a material in which a portion of Al, Si, or Mg of these is replaced with Zn, Be, or the like. These materials have a large bandgap and excellent insulation properties. When the nonmagnetic layer 20 is made of a nonmagnetic insulating material, the nonmagnetic layer 20 is a tunnel barrier layer. Examples of nonmagnetic metals include Cu, Au, and Ag. Examples of nonmagnetic semiconductors include Si, Ge, CuInSe₂, CuGaSe₂, and Cu(In,Ga)Se₂.

For example, the thickness of the nonmagnetic layer 20 is 20 Å or larger and may be 25 Å or larger. If the thickness of the nonmagnetic layer 20 is large, the resistance area product (RA) of the magnetic domain wall motion element 100 increases. The resistance area product (RA) of the magnetic domain wall motion element 100 is preferably 1×10⁴ Ωμm² or larger and is more preferably 5×10⁴ Ωμm² or larger. The resistance area product (RA) of the magnetic domain wall motion element 100 is expressed by the product of the element resistance of one magnetic domain wall motion element 100 and the element cross-sectional area of the magnetic domain wall motion element 100 (area of a cut surface of the nonmagnetic layer 20 cut along an xy plane).

The reference layer 30 sandwiches the nonmagnetic layer 20 together with the magnetic domain wall motion layer 10. The reference layer 30 is located at a position where at least a portion thereof overlaps the magnetic domain wall motion layer 10 in the z direction. The magnetization of the reference layer 30 is less likely to be reversed than the magnetization of the third area A3 of the magnetic domain wall motion layer 10. The magnetization of the reference layer 30 is fixed such that the direction thereof does not change when an external force to the extent that the magnetization of the third area A3 is reversed has been applied. The reference layer 30 may be referred to as a fixed layer.

For example, the reference layer 30 contains a ferromagnetic material. The reference layer 30 may be made of an antiferromagnetic material such as Mn₃Sn. For example, the reference layer 30 contains a material with which a coherent tunneling effect is likely to be achieved between the reference layer 30 and the magnetic domain wall motion layer 10. For example, the reference layer 30 contains a metal selected from the group consisting of Cr, Mn, Co, Fe and Ni, an alloy containing one or more kinds of these metals, an alloy containing these metals and at least one or more kinds of elements of B, C, and N, or the like. For example, the reference layer 30 is made of Co—Fe, Co—Fe—B, or Ni—Fe.

For example, the reference layer 30 may be made of a Heusler alloy. A Heusler alloy is a half-metal having a high spin polarizability. A Heusler alloy is an intermetallic compound having a chemical composition of XYZ or X₂YZ. X represents a transition metal element or a noble metal element of the Co group, the Fe group, the Ni group, or the Cu group on the periodic table. Y represents a transition metal of the Mn group, the V group, the Cr group, or the Ti group, or a kind of an element represented by X. Z represents a typical element of Group III to Group V. Examples of a Heusler alloy include Co₂FeSi, Co₂FeGe, Co₂FeGa, Co₂MnSi, Co₂Mn₁₋ₐFeₐAl_{b}Si_{1-b}, and Co₂FeGe_{1-c}Ga_{c}.

The first magnetization fixing portion 40 and the second magnetization fixing portion 50 are connected to the magnetic domain wall motion layer 10. The first magnetization fixing portion 40 and the second magnetization fixing portion 50 are connected to the magnetic domain wall motion layer 10 at different positions. The first magnetization fixing portion 40 and the second magnetization fixing portion 50 are separated from each other in the x direction. The first magnetization fixing portion 40 fixes the magnetization of the first area A1. The second magnetization fixing portion 50 fixes the magnetization of the second area A2.

For example, the first magnetization fixing portion 40 and the second magnetization fixing portion 50 include a ferromagnetic layer. For example, the first magnetization fixing portion 40 and the second magnetization fixing portion 50 may be a single ferromagnetic layer or may form a structure in which a plurality of layers are laminated. For example, a material similar to those of the magnetic domain wall motion layer 10 and the reference layer 30 can be applied to the first magnetization fixing portion 40 and the second magnetization fixing portion 50.

In addition, the first magnetization fixing portion 40 and the second magnetization fixing portion 50 are not limited to a ferromagnetic material. When the first magnetization fixing portion 40 and the second magnetization fixing portion 50 are not made of a ferromagnetic material, due to sudden change in current density of a current flowing through the magnetic domain wall motion layer 10 in an area overlapping the first magnetization fixing portion 40 or the second magnetization fixing portion 50, movement of the magnetic domain wall DW is restricted, and the magnetization of the first area A1 and the second area A2 is fixed.

The thicknesses of the first magnetization fixing portion 40 and the second magnetization fixing portion 50 in the z direction may differ from each other. If the thicknesses of the first magnetization fixing portion 40 and the second magnetization fixing portion 50 differ from each other, it is easy to make the magnetization directions of the first area A1 and the second area A2 opposite to each other during manufacturing.

The first wiring 60 is connected to the first magnetization fixing portion 40. The first wiring 60 is connected to a surface of the first magnetization fixing portion 40 on a side opposite to the surface which comes into contact with the magnetic domain wall motion layer 10.

The first wiring 60 has the first part 601 extending in the y direction. In the examples shown in FIGS. 3 to 5, the first wiring 60 is constituted of the first part 601. The first part 601 extends in the positive y direction with respect to the magnetic domain wall motion layer 10.

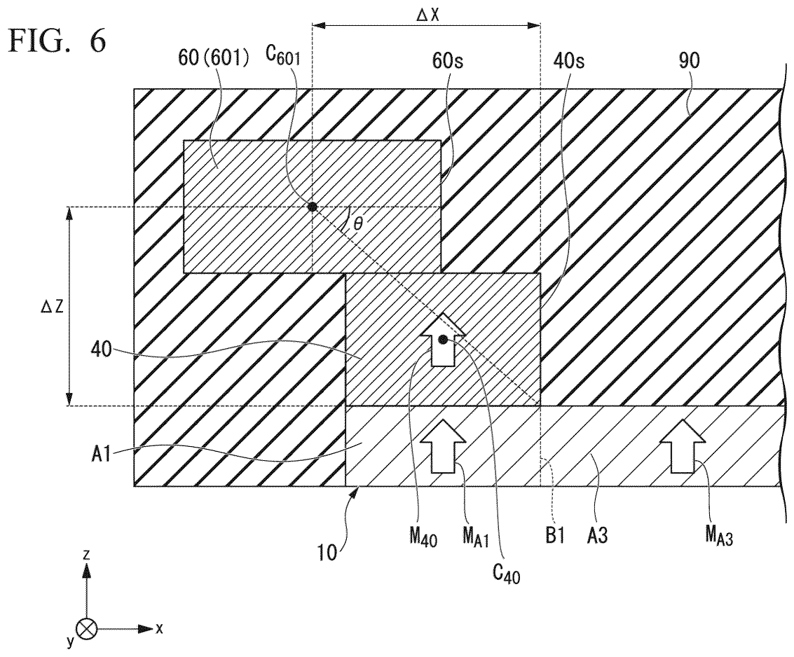

FIG. 6 is an enlarged view in which a part in the vicinity of the first wiring 60 of the magnetic domain wall motion element 100 according to the first embodiment is enlarged. For example, a center C₆₀₁ of the first part 601 of the first wiring 60 in the x direction is located at a position farther away from the second magnetization fixing portion 50 than a center C₄₀ of the first magnetization fixing portion 40 in the x direction. For example, a side surface 40s of the first magnetization fixing portion 40 on the second magnetization fixing portion 50 side is located at a position farther away from the second magnetization fixing portion 50 than a side surface 60s of the first wiring 60 on the second magnetization fixing portion 50 side. The relationship between the first magnetization fixing portion 40 and the first wiring 60 is not limited to this example. The center C₆₀₁ may be located at a position in the positive x direction from the center C₄₀, and the side surface 60s may be located at a position in the positive x direction from the side surface 40s. For example, regarding the upper surface of the first magnetization fixing portion 40, the entire surface may be covered by the first wiring 60, or only a portion may be covered by the first wiring 60.

For example, a distance ΔX between the side surface 40s and the center C₆₀₁ may be longer than a distance ΔZ between an interface between the magnetic domain wall motion layer 10 and the first magnetization fixing portion 40 and the center C₆₀₁ in the z direction. If the distance ΔX is longer than the distance ΔZ, the component of a magnetic field in the z direction generated at a boundary B1 between the first area A1 and the third area A3 of the magnetic domain wall motion layer 10 increases. In addition, the distance ΔX and the distance ΔZ may satisfy the relationship of 0.25<ΔX/ΔZ<4.0 or may satisfy the relationship of 0.5<ΔX/ΔZ<2.0. An angle θ formed by an xy plane passing through the center C₆₀₁ and a line connecting the center C₆₀₁ and the boundary B1 at the shortest distance is preferably 45° or smaller.

For example, the distance ΔX between the side surface 40s and the center C₆₀₁ is 2 μm or shorter and may be 1μm or shorter. If the distance ΔX is within this range, it is possible to apply a magnetic field sufficient to affect the operation of the magnetic domain wall DW at the boundary B1.

The second wiring 70 is connected to the second magnetization fixing portion 50. The second wiring 70 is connected to a surface of the second magnetization fixing portion 50 on a side opposite to the surface which comes into contact with the magnetic domain wall motion layer 10. The second wiring 70 may cover a portion on the upper surface of the second magnetization fixing portion 50 or may cover the entire surface.

The second wiring 70 has the first part 701 extending in the y direction. In the examples shown in FIGS. 3 and 4, the second wiring 70 is constituted of the first part 701. The first part 701 extends in the same direction as that of the first part 601 with respect to the magnetic domain wall motion layer 10. For example, when the first part 601 extends in the positive y direction with respect to the magnetic domain wall motion layer 10, the first part 701 also extends in the positive y direction with respect to the magnetic domain wall motion layer 10. For example, when the first part 601 extends in the negative y direction with respect to the magnetic domain wall motion layer 10, the first part 701 also extends in the negative y direction with respect to the magnetic domain wall motion layer 10.

The relationship between the second wiring 70 and the second magnetization fixing portion 50 is similar to the relationship between the first wiring 60 and the first magnetization fixing portion 40. The relationship between the second wiring 70 and the second magnetization fixing portion 50 may be a linear symmetric relationship in the x direction based on the positional relationship between the first wiring 60 and the first magnetization fixing portion 40, and the center of the magnetic domain wall motion layer 10 in the x direction.

For example, the center of the first part 701 of the second wiring 70 in the x direction may be located at a position farther away from the first magnetization fixing portion 40 than the center of the second magnetization fixing portion 50 in the x direction, for example. In addition, for example, a side surface of the second magnetization fixing portion 50 on the first magnetization fixing portion 40 side may be located at a position farther away from the first magnetization fixing portion 40 than a side surface of the second wiring 70 on the first magnetization fixing portion 40 side.

The magnetic domain wall motion element 100 may have a layer having a constitution other than those described above. For example, a magnetic layer may be provided on a surface of the reference layer 30 on a side opposite to the nonmagnetic layer 20 with a spacer layer therebetween. The reference layer 30, the spacer layer, and the magnetic layer form a synthetic antiferromagnetic structure (SAF structure). The synthetic antiferromagnetic structure is constituted of two magnetic layers sandwiching the nonmagnetic layer therebetween. Due to antiferromagnetic coupling between the reference layer 30 and the magnetic layer, the coercive force of the reference layer 30 becomes greater than that in the case of having no magnetic layer. For example, the magnetic layer contains a ferromagnetic material and may also contain an antiferromagnetic material such as IrMn or PtMn. For example, the spacer layer contains at least one selected from the group consisting of Ru, Ir, and Rh.

For example, the magnetization direction of each of the layers of the magnetic domain wall motion element 100 can be confirmed by measuring a magnetization curve. For example, the magnetization curve can be measured using a magneto optical Kerr effect (MOKE). Measurement using the MOKE is a measurement method performed using a magneto optical effect (magnetic Kerr effect) in which linearly polarized light is incident on a measurement target, causing rotation or the like in its polarization direction.

The magnetic domain wall motion element 100 is formed by a step of laminating each of the layers, and a processing step of processing a portion of each of the layers into a predetermined shape. Each of the layers can be laminated using a sputtering method, a chemical vapor deposition (CVD) method, an electron beam evaporation method (EB evaporation method), an atom laser deposition (ALD) method, or the like. Each of the layers can be processed using photolithography, etching (for example, Ar etching), and the like.

Next, writing operation of a signal in the magnetic array MA and reading operation of a signal from the magnetic array MA will be described.

Writing operation of a signal in the magnetic array MA will be described. Writing operation is performed by applying a writing pulse to the magnetic domain wall motion element 100. For example, a step of applying this writing pulse is performed by the processor executing an application program stored in the control unit 6.

First, a magnetic domain wall motion element 100 to which a pulse is to be applied is selected. When the magnetic array MA is used as a magnetic memory, the magnetic domain wall motion element 100 to which a pulse is to be applied is an element for storing data. When the magnetic array MA is used as a neural network, the magnetic domain wall motion element 100 to which a pulse is to be applied is an element for performing learning.

The magnetic domain wall motion element 100 to which a pulse is to be applied among a plurality of magnetic domain wall motion elements 100 is controlled by the control unit 6 in accordance with the control program. The control unit 6 turns on the first switching element SW1 and the second switching element SW2 connected to the magnetic domain wall motion element 100 to which a pulse is to be applied, and turns off the first switching elements SW1 and the second switching elements SW2 connected to other magnetic domain wall motion elements 100.

Next, a writing pulse is applied to the magnetic domain wall motion element 100 which is a writing target. A writing pulse may be rectangular waves, may be spike waves, or may have other waveforms.

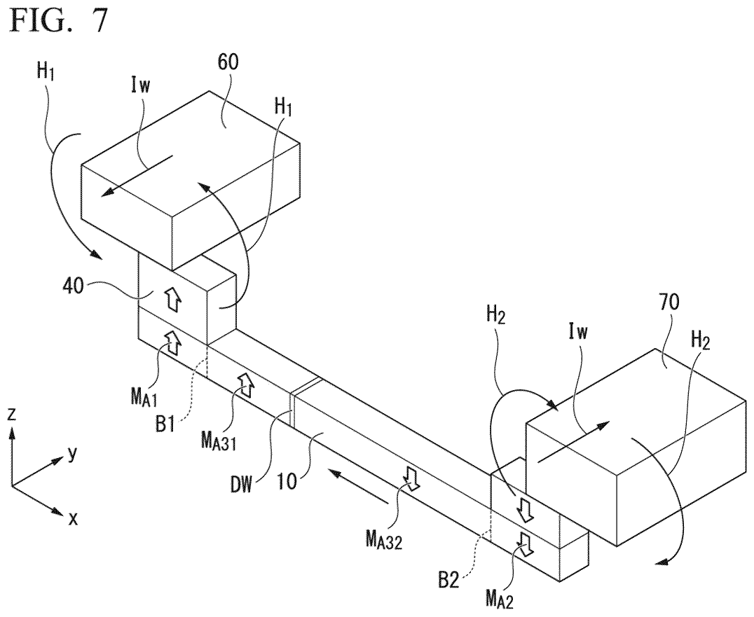

FIG. 7 is a schematic explanatory view of writing operation of the magnetic domain wall motion element 100 according to the present embodiment. If a writing pulse is applied to the magnetic domain wall motion element 100, a writing current Iw flows. For example, the writing current Iw flows through the first wiring 60, the first magnetization fixing portion 40, the magnetic domain wall motion layer 10, the second magnetization fixing portion 50, and the second wiring 70 in this order. In addition, the writing current Iw may inversely flow through the second wiring 70, the second magnetization fixing portion 50, the magnetic domain wall motion layer 10, the first magnetization fixing portion 40, and the first wiring 60 in this order. The flowing direction of the writing current Iw changes depending on the data to be written.

For example, when the writing current Iw flows through the first wiring 60, the first magnetization fixing portion 40, the magnetic domain wall motion layer 10, the second magnetization fixing portion 50, and the second wiring 70 in this order, the magnetic domain wall DW moves in the negative x direction. If the writing current Iw continuously flows in this direction, the magnetic domain wall DW moves within the third area A3 and reaches the boundary B1 between the first area A1 and the third area A3. The magnetic domain wall DW is likely to be trapped in the vicinity of the boundary B1. This is because the boundary B1 is a position where the current density structurally changes significantly and it is a position likely to be damaged when the first magnetization fixing portion 40 is produced. If the magnetic domain wall DW is trapped in the vicinity of the boundary B1, the magnetic domain wall motion element 100 cannot be operated stably any longer.

The writing current Iw flowing through the first wiring 60 generates an Oersted magnetic field H₁. The Oersted magnetic field H₁ is generated around the first wiring 60 in accordance with the right-handed screw rule. The Oersted magnetic field H₁ acts in the positive z direction at the boundary B1. The Oersted magnetic field H₁ acting in the positive z direction at the boundary B1 inhibits the magnetic domain wall DW from approaching the boundary B1. In the vicinity of the boundary B1, the magnetic domain wall DW is likely to be trapped as described above. The Oersted magnetic field H₁ inhibits the magnetic domain wall DW from approaching the boundary B1 and supports stable operation of the magnetic domain wall motion element 100.

The writing current Iw flowing through the second wiring 70 also generates an Oersted magnetic field H₂. The Oersted magnetic field H₂ is generated around the second wiring 70 in accordance with the right-handed screw rule. The Oersted magnetic field H₂ acts in the positive z direction at the boundary B1. The Oersted magnetic field H₂ acting in the positive z direction at the boundary B1 inhibits the magnetic domain wall DW from approaching the boundary B1. However, the Oersted magnetic field H₂ acting on the boundary B1 is sufficiently smaller than the Oersted magnetic field H₁, and an influence thereof is small.

On the contrary to the foregoing example, if the writing current Iw flows through the second wiring 70, the second magnetization fixing portion 50, the magnetic domain wall motion layer 10, the first magnetization fixing portion 40, and the first wiring 60 in this order, the direction of the writing current Iw becomes opposite, and the magnetic domain wall DW moves in the positive x direction. If the writing current Iw continuously flows in this direction, the magnetic domain wall DW moves within the third area A3 and reaches a boundary B2 between the second area A2 and the third area A3. The magnetic domain wall DW is likely to be trapped in the vicinity of the boundary B2. This is because the boundary B2 is a position where the current density structurally changes significantly and it is a position likely to be damaged when the second magnetization fixing portion 50 is produced. If the magnetic domain wall DW is trapped in the vicinity of the boundary B2, the magnetic domain wall motion element 100 cannot be operated stably any longer.

If the flowing direction of the writing current Iw changes, the directions of the Oersted magnetic field H₁ generated around the first wiring 60 and the Oersted magnetic field H₂ generated around the second wiring 70 also become opposite to each other. Both the Oersted magnetic field H₁ and the Oersted magnetic field H₂ act in the negative z direction at the boundary B2. The Oersted magnetic fields H₁ and H₂ acting in the negative z direction at the boundary B2 inhibit the magnetic domain wall DW from approaching the boundary B2 and curb trapping of the magnetic domain wall DW.

The magnetic array MA completes writing operation when a computer executes an operation program as described above.

Next, reading operation of a signal from the magnetic array MA will be described. For example, reading operation is performed by the processor executing the control program stored in the control unit 6.

The control program has a procedure of selecting a magnetic domain wall motion element 100 to which a pulse is to be applied and a procedure of applying a pulse.

First, the pulse application device 3 selects a magnetic domain wall motion element 100 to which a reading pulse is to be applied in accordance with the control program. When the magnetic array MA is used as a magnetic memory, the magnetic domain wall motion element 100 to which a reading pulse is to be applied is an element for reading data. When the magnetic array MA is used as a neural network, application of a reading pulse to a predetermined magnetic domain wall motion element 100 corresponds to multiplication operation of the input and the weight. That is, when the magnetic array MA is used as a neural network, reading operation is operation of identifying the neural network.

The magnetic domain wall motion element 100 to which a pulse is to be applied among a plurality of magnetic domain wall motion elements 100 is controlled by the control unit 6. The control unit 6 turns on the third switching element SW3 and the second switching element SW2 connected to the magnetic domain wall motion element 100 to which a pulse is to be applied, and turns off the third switching elements SW3 and the second switching elements SW2 connected to other magnetic domain wall motion elements 100.

Next, the pulse application device 3 applies a reading pulse to a predetermined magnetic domain wall motion element 100 in accordance with the control program. For example, a reading pulse applied between the reference layer 30 and the first magnetization fixing portion 40 or the second magnetization fixing portion 50. The voltage of a reading pulse is a voltage capable of obtaining a current density lower than a critical current density required to move the magnetic domain wall DW of the magnetic domain wall motion layer 10. That is, a reading pulse does not move the magnetic domain wall DW.

The resistance detection device 4 detects the resistance value of the magnetic domain wall motion element 100 to which a reading pulse has been applied. For example, the output unit 5 outputs the arithmetic operation results to the outside.

In the magnetic domain wall motion element 100 according to the present embodiment, the Oersted magnetic fields H₁ and H₂ generated by the writing current Iw flowing through the first wiring 60 and the second wiring 70 curb approach of the magnetic domain wall DW to the boundaries B1 and B2 and curb trapping of the magnetic domain wall DW in the vicinity of the boundaries B1 and B2. Therefore, the magnetic domain wall motion element 100 according to the present embodiment can be operated stably.

Thus far, an example of a specific constitution of a magnetic domain wall motion element and a magnetic array has been described with the magnetic domain wall motion element 100 as an example, but a magnetic array including a magnetic domain wall motion element is not limited to this example.

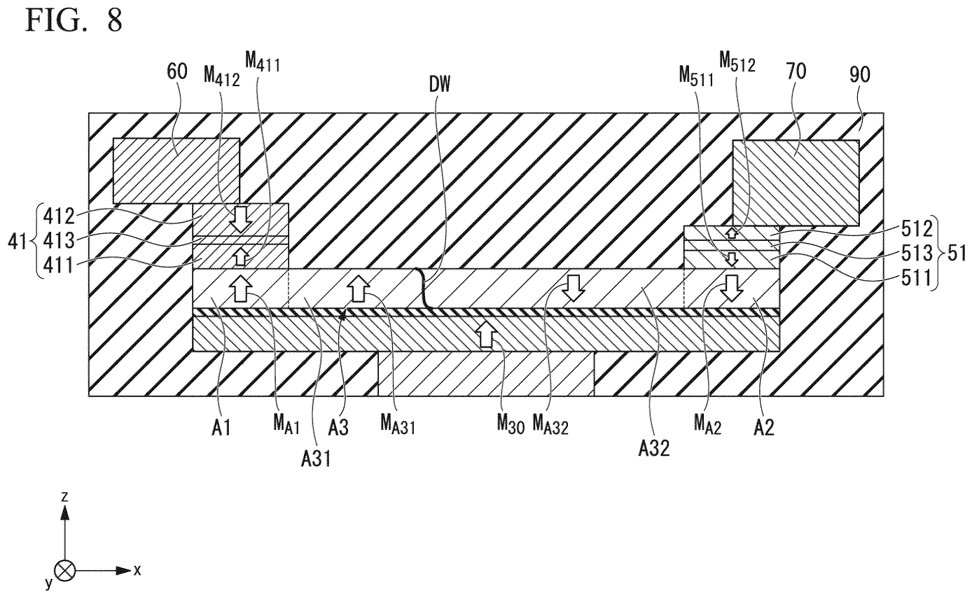

For example, FIG. 8 is a cross-sectional view of the magnetic domain wall motion element according to a first modification example. The magnetic domain wall motion element shown in FIG. 8 differs from the magnetic domain wall motion element 100 in that the first magnetization fixing portion 40 has a three-layer structure of a first ferromagnetic layer 411, a second ferromagnetic layer 412, and a spacer layer 413, and the second magnetization fixing portion 50 has a three-layer structure of a first ferromagnetic layer 511, a second ferromagnetic layer 512, and a spacer layer 513.

The first ferromagnetic layer 411 and the second ferromagnetic layer 412 form an SAF structure in which they are magnetically coupled to each other with the spacer layer 413 sandwiched therebetween. The first ferromagnetic layer 511 and the second ferromagnetic layer 512 form an SAF structure in which they are magnetically coupled to each other with the spacer layer 513 sandwiched therebetween. In this case, the magnetization M_{A1} is oriented in the same direction as that of the magnetization of the magnetic layer closest to the magnetic domain wall motion layer 10 (first ferromagnetic layer 411) in the first magnetization fixing portion 40, and the magnetization M_{A2} is oriented in the same direction as that of the magnetization of the magnetic layer closest to the magnetic domain wall motion layer 10 (first ferromagnetic layer 511) in the second magnetization fixing portion 50.

If the first magnetization fixing portion 40 and the second magnetization fixing portion 50 form an SAF structure, the stability of the magnetization of the first magnetization fixing portion 40 and the second magnetization fixing portion 50 is enhanced so that the magnetization stability of the first area A1 and the second area A2 is enhanced.

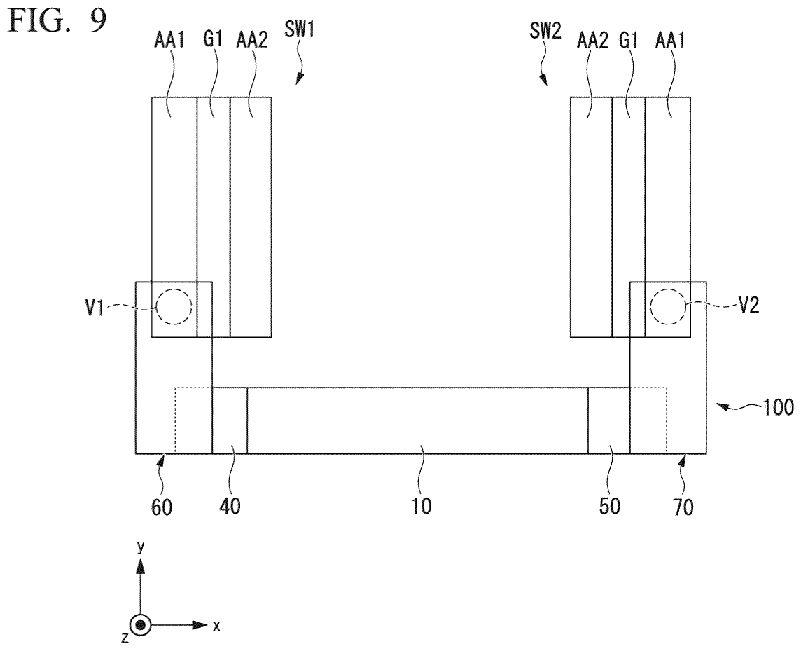

In addition, for example, FIG. 9 is a plan view of a part in the vicinity of the magnetic domain wall motion element of the magnetic memory according to a second modification example. The magnetic domain wall motion element shown in FIG. 9 differs from the magnetic domain wall motion element 100 in longitudinal directions of the first switching element SW1 and the second switching element SW2. Since the first switching element SW1 and the second switching element SW2 are located in a layer different from that of the magnetic domain wall motion element 100, the longitudinal directions thereof can be set arbitrarily.

In addition, the magnetic domain wall motion element 100 is a bottom pin structure in which the reference layer 30 is closer to the substrate Sub than the magnetic domain wall motion layer 10, but it may be a top pin structure in which the reference layer 30 is farther away from the substrate Sub than the magnetic domain wall motion layer 10. In the case of a top pin structure, the magnetic domain wall motion element has a shape which is upside down.

### Second Embodiment

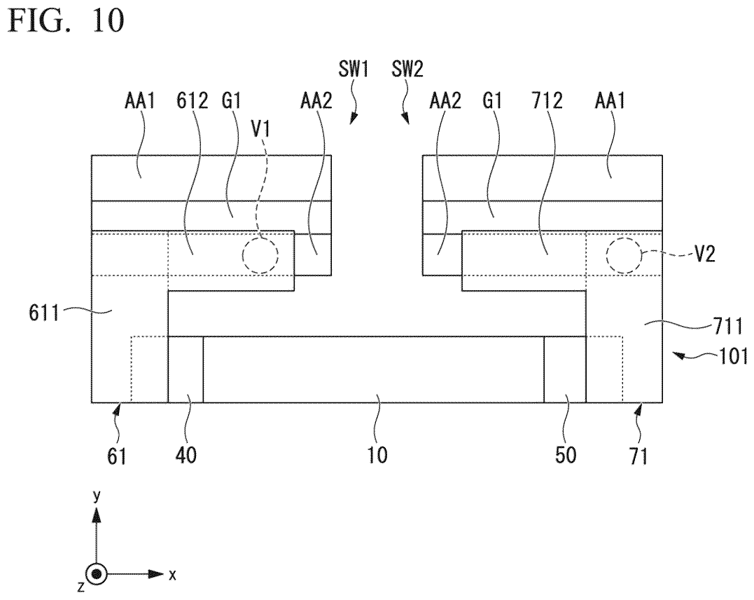

FIG. 10 is a plan view of a part in the vicinity of a magnetic domain wall motion element 101 of the magnetic array according to a second embodiment. In the magnetic array according to the second embodiment, the shape of the magnetic domain wall motion element 101 differs from that of the magnetic domain wall motion element 100 according to the first embodiment. In the second embodiment, the same reference signs are applied to constituent elements similar to those of the first embodiment, and description thereof will be omitted.

In the magnetic domain wall motion element 101, the shapes of a first wiring 61 and a second wiring 71 differ from those of the first wiring 60 and the second wiring 70 of the magnetic domain wall motion element 100.

The first wiring 61 has a first part 611 and a second part 612. The first part 611 extends in the y direction. For example, the first part 611 extends in the positive y direction with respect to the magnetic domain wall motion layer 10. For example, a first end of the first part 611 comes into contact with the first magnetization fixing portion 40. For example, the first part 611 extends in the positive y direction from a part which comes into contact with the first magnetization fixing portion 40. For example, the first part 611 satisfies the constitution of the first wiring 60 described above.

The second part 612 is a part connected to a second end of the first part 611. The second end is an end portion of the first part 611 on a side far from the magnetic domain wall motion layer 10. The second part 612 has a part extending in the x direction. The second part 612 may be constituted of only a part extending in the x direction. The part extending in the x direction in the second part 612 extends in the positive x direction in the direction of the second wiring 71 from the first part 611. For example, the second part 612 may extend in the positive x direction from the second end of the first part 611.

For example, the length of the part extending in the x direction in the second part 612 is equal to or smaller than half the length of the magnetic domain wall motion layer 10 in the x direction. If the second part 612 satisfies this relationship, a risk of the first wiring 61 and the second wiring 71 coming into contact with each other can be avoided.

The second wiring 71 has a first part 711 and a second part 712. The first part 711 extends in the y direction. For example, the first part 711 extends in the same direction as that of the first part 611 with respect to the magnetic domain wall motion layer 10. For example, when the first part 611 extends in the positive y direction with respect to the magnetic domain wall motion layer 10, the first part 711 also extends in the positive y direction with respect to the magnetic domain wall motion layer 10. For example, when the first part 611 extends in the negative y direction with respect to the magnetic domain wall motion layer 10, the first part 711 also extends in the negative y direction with respect to the magnetic domain wall motion layer 10. For example, a first end of the first part 711 comes into contact with the second magnetization fixing portion 50. For example, the first part 711 extends in the positive y direction from a part which comes into contact with the second magnetization fixing portion 50. For example, the first part 711 satisfies the constitution similar to that of the second wiring 70.

The second part 712 is a part connected to a second end of the first part 711. The second end is an end portion of the first part 711 on a side far from the magnetic domain wall motion layer 10. The second part 712 has a part extending in the x direction. The second part 712 may be constituted of only a part extending in the x direction. The part extending in the x direction in the second part 712 extends in the negative x direction in the direction of the first wiring 61 from the first part 711. For example, the second part 712 may extend in the negative x direction from the second end of the first part 711.

For example, the length of the part extending in the x direction in the second part 712 may be equal to or smaller than half the length of the magnetic domain wall motion layer 10 in the x direction. If the second part 712 satisfies this relationship, a risk of the first wiring 61 and the second wiring 71 coming into contact with each other can be avoided.

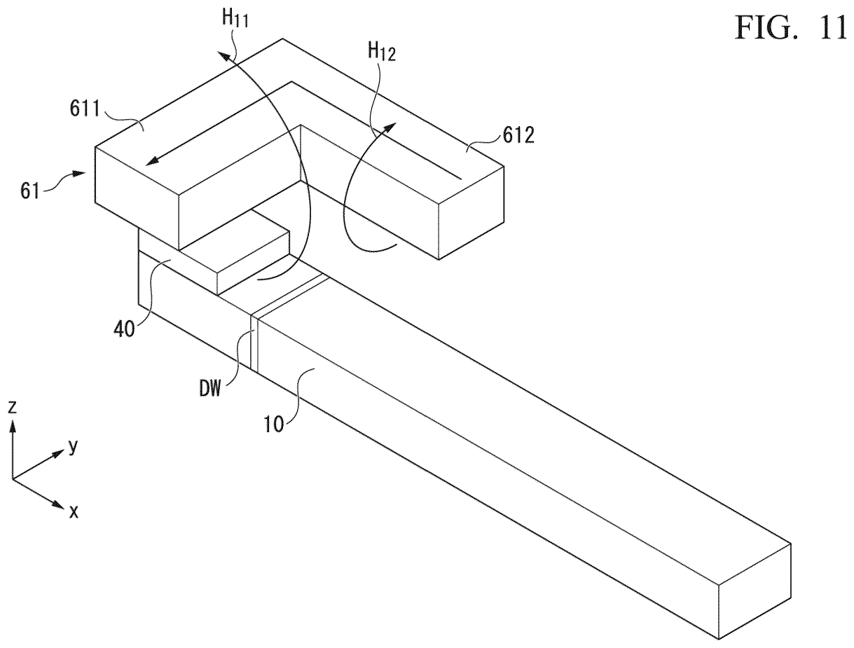

FIG. 11 is a schematic explanatory view of writing operation of the magnetic domain wall motion element 101 according to the present embodiment. If a writing pulse is applied to the magnetic domain wall motion element 101, the writing current Iw flows. The flowing direction of the writing current Iw changes depending on the data to be written.

The writing current Iw flowing through the first part 611 generates an Oersted magnetic field H₁₁, and the writing current Iw flowing through the second part 612 generates an Oersted magnetic field H₁₂. Both the Oersted magnetic fields H₁₁ and H₁₂ act in the positive z direction at the boundary B1. The Oersted magnetic field H₁ acting in the positive z direction at the boundary B1 inhibits the magnetic domain wall DW from approaching the boundary B1. As a result, in the magnetic domain wall motion layer 10, trapping of the magnetic domain wall DW can be curbed.

The second wiring 71 is also similar to the first wiring. Both the Oersted magnetic field generated in the first part 711 and the Oersted magnetic field generated in the second part 712 inhibit the magnetic domain wall DW from approaching the boundary B2.

In the first wiring 60 of the magnetic domain wall motion element 101 according to the present embodiment, both the Oersted magnetic field H₁₁ generated in the first part 611 and the Oersted magnetic field H₁₂ generated in the second part 612 inhibit the magnetic domain wall DW from approaching the boundary B1. Therefore, the magnetic domain wall motion element 101 according to the present embodiment can be operated stably.

### Third Embodiment

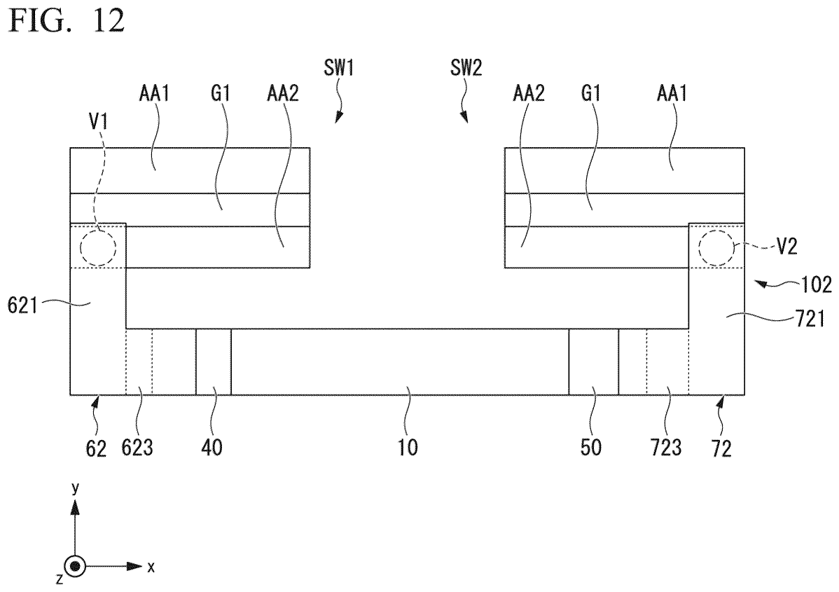

FIG. 12 is a plan view of a part in the vicinity of a magnetic domain wall motion element 102 of the magnetic array according to a third embodiment. In the magnetic array according to the third embodiment, the shape of the magnetic domain wall motion element 102 differs from that of the magnetic domain wall motion element 100 according to the first embodiment. In the third embodiment, the same reference signs are applied to constituent elements similar to those of the first embodiment, and description thereof will be omitted.

In the magnetic domain wall motion element 102, the shapes of a first wiring 62 and a second wiring 72 differ from those of the first wiring 60 and the second wiring 70 of the magnetic domain wall motion element 100.

The first wiring 62 has a first part 621 and a third part 623. The first part 621 extends in the y direction. For example, the first part 621 extends in the positive y direction with respect to the magnetic domain wall motion layer 10. For example, the first part 621 satisfies the constitution of the first wiring 60 described above.

The third part 623 is a part connected to a first end and a first connection surface of the first part 621. The first end is an end portion of the first part 621 on a side closer to the magnetic domain wall motion layer 10. The first connection surface is a surface where the first wiring 62 and the first magnetization fixing portion 40 come into contact with each other. The third part 623 has a part extending in the x direction. The third part 623 may be constituted of only a part extending in the x direction. For example, the third part 623 extends in the negative x direction in a direction in which it is separated from the second wiring 72 from the first connection surface.

The distance between a boundary between the first area A1 and the third area A3 and the first part 621 can be increased using the third part 623. By increasing this distance, the direction of the Oersted magnetic field acting on the boundary between the first area A1 and the third area A3 can be brought closer to the z direction. In addition, it is possible to reduce an influence of the Oersted magnetic field generated by the first part 621 on the third area A3 in which the magnetic domain wall DW moves.

Even when the third part 623 is provided, the distance ΔX and the distance ΔZ may satisfy the relationship of 0.25<ΔX/ΔZ<4.0 or may satisfy the relationship of 0.5<ΔX/ΔZ<2.0. The length of the part extending in the x direction in the third part 623 can be designed such that ΔX and ΔZ satisfy the foregoing relationships. Since the distance between the boundary between the first area A1 and the third area A3 and the first part 621 is not excessively long, an Oersted magnetic field having a sufficient intensity can be applied to the boundary B1 between the first area A1 and the third area A3.

The second wiring 72 has a first part 721 and a third part 723. The first part 721 extends in the y direction. For example, the first part 721 extends in the positive y direction which is the same direction as that of the first part 621 with respect to the magnetic domain wall motion layer 10. For example, the first part 721 satisfies the constitution of the second wiring 70 described above.

The third part 723 is a part connected to a first end of the first part 721 and a second connection surface. The first end is an end portion of the first part 721 on a side closer to the magnetic domain wall motion layer 10. The second connection surface is a surface where the second wiring 72 and the second magnetization fixing portion come into contact with each other. The third part 723 has a part extending in the x direction. The third part 723 may be constituted of only a part extending in the x direction. The third part 723 extends in the positive x direction in a direction in which it is separated from the first wiring 62 from the second connection surface.

The third part 723 can increase the distance between the boundary B2 between the second area A2 and the third area A3 and the first part 721. For example, the length of the part extending in the x direction in the third part 723 is similar to that of the third part 623.

In the magnetic domain wall motion element 102 according to the present embodiment, due to the third part 623, the distance between the first part 621 and the boundary B1 between the first area A1 and the third area A3 can be increased, and the direction of the magnetic field acting on this boundary B1 can be brought closer to the z direction. In addition, it is possible to reduce an adverse influence of the Oersted magnetic field generated in the first wiring 62 on the third area A3 in which the magnetic domain wall DW moves.

### Fourth Embodiment

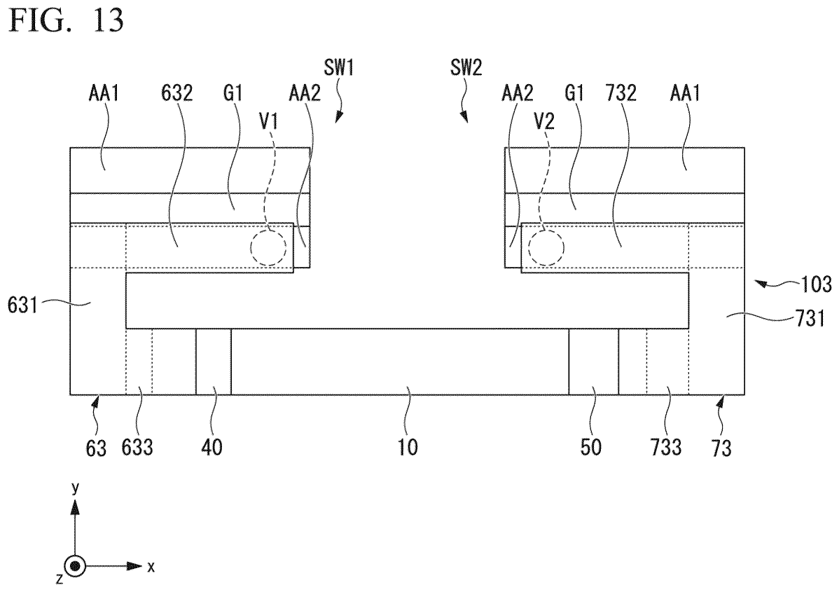

FIG. 13 is a plan view of a part in the vicinity of a magnetic domain wall motion element 103 of the magnetic array according to a fourth embodiment. In the magnetic array according to the fourth embodiment, the shape of the magnetic domain wall motion element 103 differs from that of the magnetic domain wall motion element 100 according to the first embodiment. In the fourth embodiment, the same reference signs are applied to constituent elements similar to those of the first embodiment, and description thereof will be omitted.

In the magnetic domain wall motion element 103, the shapes of a first wiring 63 and a second wiring 73 differ from those of the first wiring 60 and the second wiring 70 of the magnetic domain wall motion element 100.

The first wiring 63 includes a first part 631, a second part 632, and a third part 633. The first part 631 corresponds to the first wiring 60 according to the first embodiment. The second part 632 corresponds to the second part 612 according to the second embodiment. The third part 633 corresponds to the third part 623 according to the third embodiment. In the case of the fourth embodiment, the length of the part extending in the x direction in the second part 632 may be shorter than the sum of half the length of the magnetic domain wall motion element 10 in the x direction and the length of the third part 633. By satisfying this relationship, contact between the first wiring 63 and the second wiring 73 can be avoided.

The second wiring 73 includes a first part 731, a second part 732, and a third part 733. The first part 731 corresponds to the second wiring 70 according to the first embodiment. The second part 732 corresponds to the second part 712 according to the second embodiment. The third part 733 corresponds to the third part 723 according to the third embodiment. In the case of the fourth embodiment, the length of the part extending in the x direction in the second part 732 may be shorter than the sum of half the length of the magnetic domain wall motion element 10 in the x direction and the length of the third part 733.

The magnetic domain wall motion element 103 according to the fourth embodiment exhibits a combined effect of the magnetic domain wall motion element 101 according to the second embodiment and the magnetic domain wall motion element 102 according to the third embodiment.

Hereinabove, preferred embodiments of the present disclosure have been described in detail, but the present disclosure is not limited to these embodiments. For example, characteristic constituents in each of the embodiments may be combined, or a portion may be changed within a range not changing the gist of the invention.

For example, modification examples similar to those of the first embodiment may be applied to the second embodiment to the fourth embodiment.

The magnetic array MA according to each of the embodiments described above can be applied to neuromorphic devices.

For example, a neuromorphic device has the magnetic array MA and an output conversion unit. The output conversion unit has an activation function. The output conversion unit has the resistance detection device 4 and the output unit 5. The output conversion unit converts product-sum operation results output from the common wiring CL in accordance with the activation function.

The neuromorphic device is a device for performing arithmetic operation of a neural network. The neuromorphic device artificially imitates the relationship between neurons and synapses in the human brain.

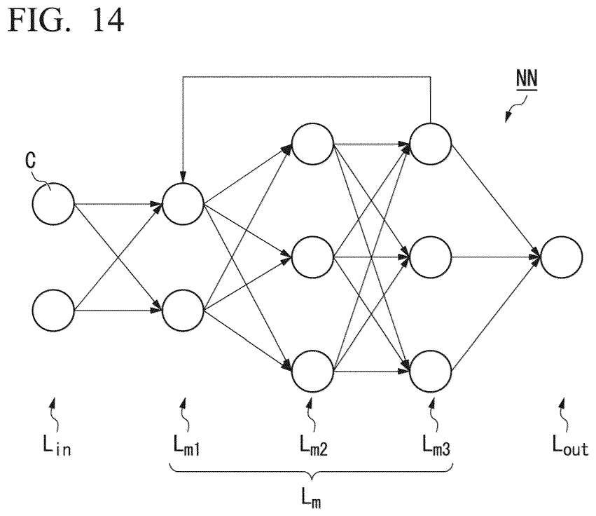

FIG. 14 is a schematic view of a neural network NN. The neural network NN has an input layer Lᵢₙ, an intermediate layer Lₘ, and an output layer Lₒᵤₜ. FIG. 14 presents an example having three intermediate layers Lₘ, but the number of intermediate layers Lₘ does not matter. Each of the input layer Lᵢₙ, the intermediate layer Lₘ, and the output layer Lₒᵤₜ has a plurality of chips C, and each of the chips C corresponds to the neuron in the brain. The input layer Lᵢₙ, the intermediate layer Lₘ, and the output layer Lₒᵤₜ are connected to each other via transmission means. The transmission means correspond to the synapses in the brain. In the neural network NN, the transmission means (synapses) perform learning to increase the rate of correct answer to a problem. Learning is a process of finding knowledge which is prone to be used in the future from information. The neural network NN performs learning through operation while changing the weight applied to the transmission means. The transmission means perform multiplication operation of multiplying an input signal by a weight, and addition operation of adding results of the multiplication operation. That is, the transmission means performs product-sum operation.

The magnetic array MA can perform product-sum operation. In the magnetic domain wall motion element 100, the resistance value changes to a multi-value form or an analog form as the position of the magnetic domain wall DW changes. Designing the resistance value of the magnetic domain wall motion element and the conductance which is a reciprocal thereof corresponds to imparting a weight to the transmission means.

For example, in FIG. 2, a current is caused to flow from the reading wiring RL toward the common wiring CL. The current (output value) output from the common wiring CL varies depending on the conductance (weight) of the magnetic domain wall motion element. That is, applying a current from the reading wiring RL toward the common wiring CL corresponds to multiplication operation in the neural network NN. In addition, the common wiring CL is connected to a plurality of magnetic domain wall motion elements which belong to the same column, and a current detected in the end portion of the common wiring CL is a value obtained by performing addition operation of results of multiplication operation in each of the magnetic domain wall motion elements. Therefore, the magnetic array MA functions as a product-sum operation unit of the neuromorphic device.

### REFERENCE SIGNS LIST

1 Integrated area
2 Peripheral area
3 Pulse application device
4 Resistance detection device
5 Output unit
6 Control unit
7 Power source
10 Magnetic domain wall motion layer
20 Nonmagnetic layer
30 Reference layer
40 First magnetization fixing portion
40s Side surface
50 Second magnetization fixing portion
60, 61, 62, 63 First wiring
60s Side surface
70, 71, 72, 73 Second wiring
80 Third wiring
90 Insulation layer
100, 101, 102, 103 Magnetic domain wall motion element
411, 511 First ferromagnetic layer
412, 512 Second ferromagnetic layer
413, 513 Spacer layer
601, 611, 621, 631, 701, 711, 721, 731 First part
612, 632, 712, 732 Second part
623, 633, 723, 733 Third part
A1 First area
A2 Second area
A3 Third area
A31 First magnetic domain
A32 Second magnetic domain
AA1 First active area
AA2 Second active area
B1 Boundary
B2 Boundary
C₄₀, C₆₀₁ Center
DW Magnetic domain wall
H₁, H₂, H₁₁, H₁₂ Oersted magnetic field
Iw Writing current
MA Magnetic array
S1 First connection surface
S2 Second connection surface
V1 First via wiring
V2 Second via wiring

1. A magnetic domain wall motion element comprising:
a magnetic domain wall motion layer;
a first magnetization fixing portion;
a second magnetization fixing portion;
a first wiring; and
a second wiring,
wherein the magnetic domain wall motion layer has a first magnetization fixed area, a second magnetization fixed area, and a magnetic domain wall motion area,
the magnetic domain wall motion area is sandwiched between the first magnetization fixed area and the second magnetization fixed area in a first direction,
the first magnetization fixing portion is connected to the first magnetization fixed area,
the second magnetization fixing portion is connected to the second magnetization fixed area,
the first wiring is connected to the first magnetization fixing portion,
the second wiring is connected to the second magnetization fixing portion,
each of the first wiring and the second wiring has a first part extending in the same direction as a second direction intersecting the first direction and a lamination direction with respect to the magnetic domain wall motion layer, and
magnetization of the first magnetization fixed area is oriented in a direction which is an outer product of a direction in which the magnetic domain wall motion layer extends with respect to a first connection surface between the first magnetization fixing portion and the first wiring, and a direction in which the first part extends in the second direction with respect to the first connection surface.

2. The magnetic domain wall motion element according to claim 1,
wherein the first wiring further includes a second part,
the second part is connected to a second end on a side opposite to a first end of the first part on a side closer to the magnetic domain wall motion layer, and
the second part has a part extending in the first direction from the first part toward a side of the second wiring.

3. The magnetic domain wall motion element according to claim 2,
wherein a length of a part extending in the first direction in the second part is equal to or smaller than half a length of the magnetic domain wall motion layer in the first direction.

4. The magnetic domain wall motion element according to claim 1,
wherein the first wiring further includes a third part,
the third part is connected to a first end of the first part on a side closer to the magnetic domain wall motion layer, and the first connection surface, and
the third part has a part extending in the first direction from the first connection surface toward a side away from the second wiring.

5. The magnetic domain wall motion element according to claim 1,
wherein a distance ΔX between a center of the first part in the first direction and a boundary between the first magnetization fixed area and the magnetic domain wall motion area, and a distance ΔZ between a center of the first part in the lamination direction and the magnetic domain wall motion layer satisfy 0.25<ΔX/ΔZ<4.

6. The magnetic domain wall motion element according to claim 4,
wherein the first wiring further includes a second part,
the second part is connected to a second end on a side opposite to a first end of the first part on a side closer to the magnetic domain wall motion layer, and
the second part has a part extending in the first direction from the first part toward a side of the second wiring.

7. The magnetic domain wall motion element according to claim 6,
wherein a length of a part extending in the first direction in the second part is shorter than a sum of half a length of the magnetic domain wall motion layer in the first direction and a length of a part extending in the first direction in the third part.

8. The magnetic domain wall motion element according to claim 1,
wherein a center of the first part in the first direction is located at a position farther away from the second magnetization fixing portion than a center of the first magnetization fixing portion in the first direction.

9. The magnetic domain wall motion element according to claim 1,
wherein a thickness of the first magnetization fixing portion differs from a thickness of the second magnetization fixing portion.

10. The magnetic domain wall motion element according to claim 1 further comprising:
a reference layer; and
a nonmagnetic layer,
wherein the nonmagnetic layer is sandwiched between the magnetic domain wall motion layer and the reference layer in the lamination direction.

11. A magnetic array comprising:
the magnetic domain wall motion element according to claim 1.
